(19) United States
(12) Patent Application Publication
(10) Pub. No.: US 2026/0371925 A1
(43) Pub. Date: Nov. 19, 2026

(54) MEASUREMENT SYSTEM AND METHOD FOR PRODUCING MEASUREMENT SYSTEM

(71) Applicant: TOPOLOGIC INC., Tokyo (JP)

(72) Inventors: Arata TAKAHASHI, Tokyo (JP); Taiki SATO, Tokyo (JP); Satoru NAKATSUJI, Tokyo (JP)

(21) Appl. No.: 19/133,591

(22) PCT Filed: Dec. 21, 2023
(86) PCT No.: PCT/JP2023/045896

§ 371 Date: May 28, 2025

(30) Foreign Application Priority Data
Dec. 28, 2022 (JP) 2022-212024

(51) Int. Cl. H10N 10/13; H10N 10/01; H10N 10/17

(52) U.S. Cl. CPC H10N 10/13; H10N 10/01; H10N 10/17

(57) ABSTRACT

A measurement system is provided, comprising at least one substrate configured to exchange heat with an object, at least one first and second thermoelectric conversion devices. The devices are arranged on a mounting surface of the substrate to generate a temperature gradient through heat exchange with the object. Thermoelectric power is generated due to the temperature gradient and includes a first electromotive force from a first thermoelectric conversion effect based on a vertical component of the gradient, and a second electromotive force from a second thermoelectric conversion effect based on an in-plane component of the gradient. The second thermoelectric conversion device is configured such that, for a temperature gradient in a substantially same direction as that of the first thermoelectric conversion device, the sign of only one of the first and second electromotive forces is opposite to a sign of the corresponding electromotive force of the first thermoelectric conversion device.

### CROSS REFERENCE TO RELATED APPLICATIONS

This application is a 371 U.S. National Phase of International Application No. PCT/JP2023/045896, filed on Dec. 21, 2023, which claims priority to Japanese Patent Application No. 2022-212024, filed Dec. 28, 2022. The entire disclosures of the above applications are incorporated herein by reference.

### BACKGROUND

### Technical Field

The present invention relates to a measuring system and a method for producing a measuring system.

### Related Art

Japanese Unexamined Patent Application Publication No. 2017-084854 discloses a technology related to a thermoelectric conversion device capable of generating a voltage on the basis of a temperature difference and suppressing a leakage magnetic field to a much greater degree than conventional devices.

The thermoelectric conversion device disclosed in the above literature includes a thermoelectric conversion element made of an antiferromagnetic material having a non-collinear spin structure and is able to exhibits the anomalous Nernst effect by passing a heat flow through the thermoelectric conversion element in a direction perpendicular to the in-plane micromagnetization direction and thus giving a temperature difference to the thermoelectric conversion device and to generate a voltage in a direction perpendicular to both the micromagnetization direction and the heat flow direction on the basis of the anomalous Nernst effect. Moreover, the thermoelectric conversion element is made of the antiferromagnetic material, which does not have strong magnetization unlike a ferromagnetic material. Thus, the thermoelectric conversion device can suppress magnetic-field leakage to a much greater extent than conventional thermoelectric conversion devices using a ferromagnetic material.

When a temperature difference (i.e., a temperature gradient) is given to a thermoelectric conversion device, an electromotive force may be generated by the Seebeck effect caused by the temperature gradient. Therefore, a thermoelectromotive force generated by the thermoelectric conversion device may include an electromotive force generated by the anomalous Nernst effect and an electromotive force generated by the Seebeck effect. For this reason, when making measurements using such a thermoelectric conversion device, it is desirable to separate the contribution of the anomalous Nernst effect to the thermoelectromotive force and the contribution of the Seebeck effect thereto.

### SUMMARY

One aspect of the present invention provides a measuring system. This measuring system includes at least one substrate configured to exchange heat with an object to be measured, at least one first thermoelectric conversion device, and at least one second thermoelectric conversion device. The substrate includes at least one placement surface. The thermoelectric conversion devices are disposed on the substrate such that a temperature gradient is generated due to exchange of heat with the object to be measured through the placement surface and are each configured to generate a thermoelectromotive force on the basis of the temperature gradient. The thermoelectromotive force includes a first electromotive force generated by a first thermoelectric conversion effect based on a component perpendicular to the placement surface of the temperature gradient and a second electromotive force generated by a second thermoelectric conversion effect based on an in-plane component parallel to the placement surface of the temperature gradient. The at least one second thermoelectric conversion device is configured such that, for a temperature gradient in a substantially same direction as that of the at least one first thermoelectric conversion device, a sign of only one of the first electromotive force and the second electromotive force is opposite to a sign of the corresponding electromotive force of the at least one first thermoelectric conversion device.

### BRIEF DESCRIPTION OF THE DRAWINGS

FIG. 1 is a diagram showing an overview of an example of a measuring system 1.

FIG. 2 is a diagram showing an overview of the example of the measuring system 1.

FIG. 3 is a diagram showing an example of a first thermoelectric conversion device 22a and a second thermoelectric conversion device 22b.

FIG. 4 is a diagram showing a modification of the thermoelectric conversion devices 22.

FIG. 5 is a diagram showing a modification of the thermoelectric conversion devices 22.

FIG. 6 is a diagram showing a modification of the thermoelectric conversion devices 22.

FIG. 7 is a diagram showing an overview of another example of the measuring system 1.

FIG. 8 is a block diagram showing the hardware configuration of a user terminal 4.

FIG. 9 is a diagram showing an example of functional units included in a processor 43.

FIG. 10 is an activity diagram showing an example of the flow of information processing performed by the measuring system 1.

FIG. 11 is an activity diagram showing the flow of the process of generating the measuring system 1.

FIG. 12 is a diagram showing an example of local heating using a laser.

FIG. 13 is a diagram showing an example of local heating using a laser.

FIG. 14 is a diagram showing a modification of the thermoelectric conversion devices 22.

### DETAILED DESCRIPTION

Now, an embodiment of the present invention will be described with reference to the drawings. Various features described in the embodiment below can be combined with each other.

A program to implement software in the present embodiment may be provided as a computer-readable non-transitory storage medium, or may be provided by download from an external server. The program may also be provided such that it is run on an external computer and its functions are implemented on a client terminal (so-called cloud computing).

The term “unit” in the present embodiment includes, for example, a combination of hardware resources implemented by a circuit in a broad sense and software information processing specifically implementable by the hardware resources. Various types of information handled in the present embodiment are represented by, for example, the physical values of signal values representing voltages or currents, high or low signal values as binary bit sets consisting of 0s or 1s, or quantum superpositions (so-called qubits) and can be communicated and subjected to a calculation on a circuit in a broad sense.

The term “circuit in a broad sense” refers to a circuit implemented by combining at least a circuit, circuitry, a processor, memory, and the like appropriately. Specifically, the term “circuit in a broad sense” includes an application-specific integrated circuit (ASIC), programmable logic devices (e.g., a simple programmable logic device (SPLD), a complex programmable logic device (CPLD), a field programmable gate array (FPGA)), and the like.

### 1. Example of Measuring System 1

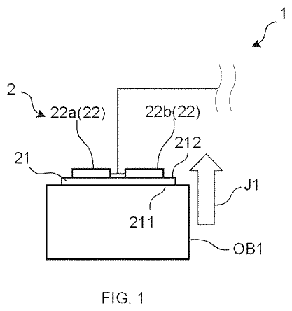

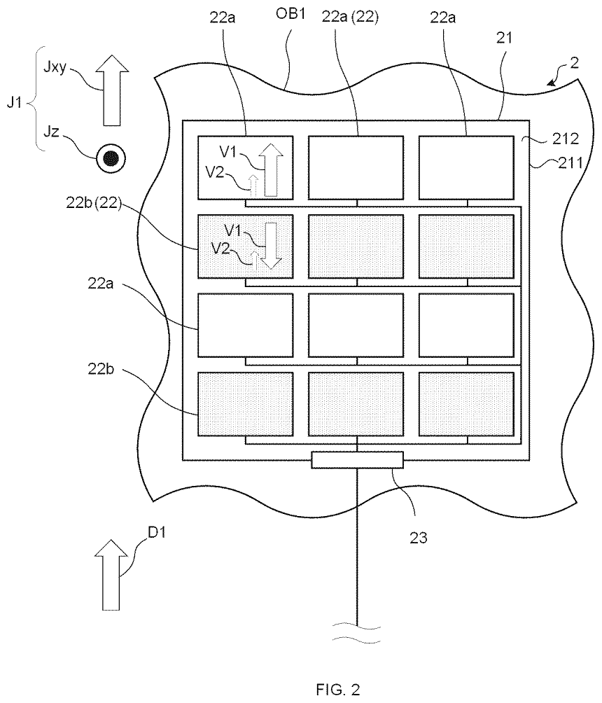

This section describes an example of a measuring system 1 with reference to FIGS. 1 and 2. FIGS. 1 and 2 are diagrams showing an overview of an example of the measuring system 1.

### 1.1. Example Configuration of Measuring system 1

As shown in FIGS. 1 and 2, the measuring system 1 includes a thermoelectric conversion system 2. The thermoelectric conversion system 2 can be connected to an external device (not shown).

### <Thermoelectric Conversion System 2>

The thermoelectric conversion system 2 is configured to generate a temperature gradient J1 by exchanging heat with an object OB1 to be measured. The heat exchange here includes the inflow of heat from the object OB1 to be measured to the thermoelectric conversion system 2 and the outflow of heat from the thermoelectric conversion system 2 to the object OB1 to be measured. The thermoelectric conversion system 2 is configured to output a thermoelectromotive force V based on the temperature gradient J1. Details of the thermoelectric conversion system 2 will be described later. Any object can be used as the object OB1 to be measured. The object OB1 to be measured does not have to be a solid and may be fluid such as a liquid or gas as long as the thermoelectric conversion system 2 can be attached thereinto.

The thermoelectric conversion system 2 includes at least one substrate 21, at least one first thermoelectric conversion device 22a, and at least one second thermoelectric conversion device 22b. In the present embodiment, thermoelectric conversion system 2 includes a single substrate 21, multiple first thermoelectric conversion devices 22a, and multiple second thermoelectric conversion devices 22b. The thermoelectric conversion system 2 according to the present embodiment may further include a port 23. While, in the present embodiment, the number of first thermoelectric conversion devices 22a and the number of second thermoelectric conversion devices 22b are equal, this is not limiting. Hereafter, the first thermoelectric conversion devices 22a and second thermoelectric conversion devices 22b may be collectively referred to as the thermoelectric conversion devices 22 for convenience's sake.

### <Substrate 21>

The substrate 21 is configured to exchange heat with the object OB1 to be measured. Thus, heat flows from the object OB1 to be measured into the substrate 21 or flows out of the object OB1 to be measured into the substrate 21. The substrate 21 may be in direct contact with the object OB1 to be measured so that heat from the object OB1 to be measured is directly exchanged not through any other component. This allows for a reduction in the measurement error of the temperature gradient J1 (to be discussed later). The substrate 21 may be in indirect contact with the object OB1 to be measured through an intermediate member such as a membrane, film, or coating material. This allows the thermoelectric conversion system 2 to be attached to a greater variety of objects OB1 to be measured. For convenience's sake, a case in which the heat of the object OB1 to be measured is transferred to the substrate 21 will be described below. The substrate 21 according to the present embodiment is a flat printed circuit board. Note that the substrate 21 does not have to take such a form. For example, the substrate 21 may be a substrate made of a semiconductor such as silicon or MgO or an insulator, the surface itself of the object OB1 to be measured, or the like. The substrate 21 may be formed to have a higher thermal conductivity than an insulating substrate 220 (to be discussed later). For example, the substrate 21 may be a metal plate, or a printed circuit board or the like surface-treated with a metal coating or the like. In the present embodiment, the substrate 21 has at least one contact surface 211 and at least one placement surface 212.

### <Contact Surface 211>

The contact surface 211 is configured to contact the object OB1 to be measured. Thus, the heat of the object OB1 to be measured is transferred to the substrate 21 through the contact surface 211. In the present embodiment, the contact surface 211 is a single continuous surface.

### <Placement Surface 212>

The placement surface 212 is a surface on which the thermoelectric conversion devices 22 (to be discussed later) are disposed. The placement surface 212 is a surface opposite to the contact surface 211 in the thickness direction of the substrate 21. In the present embodiment, the placement surface 212 is a single continuous surface.

The substrate 21 does not have to be flat and may have any shape. It may have a curved surface or a bending point. The substrate 21 may be a so-called flexible substrate, which is deformable. This facilitates measurement of the temperature gradient J1 of the object OB1 to be measured having a curved surface.

### <Thermoelectric Conversion Device 22>

The thermoelectric conversion devices 22 are disposed on the substrate 21 such that a temperature gradient J1 is generated therein on the basis of heat transferred through the placement surface 212 and are each configured to generate a thermoelectromotive force V on the basis of the temperature gradient J1. Specifically, each second thermoelectric conversion device 22b is configured such that, for a temperature gradient in a substantially same direction as the temperature gradient J1 of the at least one first thermoelectric conversion device, the sign of only one of a first electromotive force V1 and a second electromotive force V2 is opposite to the sign of the corresponding electromotive force of the at least one first thermoelectric conversion device 22a.

The temperature gradient J1 includes at least a component Jz perpendicular to the placement surface 212. The perpendicular component Jz of the temperature gradient J1 is a component perpendicular to the placement surface 212 of the temperature gradient J1. If the substrate 21 has a curved surface or the like, the direction perpendicular to the placement surface 212 can be defined by the direction of a local normal to the curved surface. For this reason, the direction perpendicular to the placement surface 212 is not necessarily uniform over the entire area of the placement surface 212.

In the present embodiment, the temperature gradient J1 can include an in-plane component Jxy. The in-plane component Jxy can be generated on the basis of variations in heat or variations in heat conduction in the in-plane direction of the substrate 21. The in-plane component Jxy is a component parallel to the placement surface 212 of the temperature gradient J1. If the substrate 21 has a curved surface or the like, the direction parallel to the placement surface 212 may be defined by a direction perpendicular to the direction of a local normal to the curved surface. For this reason, the direction parallel to the placement surface 212 is not necessarily uniform over the entire area of the placement surface 212.

Note that being “perpendicular” to one direction or plane is not limited to being perfectly perpendicular to the direction or plane and includes, for example, being perpendicular within the allowable error of dimensions or the like. Similarly, being “parallel” to one direction or plane is not limited to being perfectly parallel to the direction or plane.

### <Thermoelectromotive Force V>

As shown in FIG. 2, the above thermoelectromotive force V includes the first electromotive force V1 and second electromotive force V2. The first electromotive force V1 is a thermoelectromotive force generated by a first thermoelectric conversion effect based on the component Jz perpendicular to the placement surface 212 of the temperature gradient J1. The first thermoelectric conversion effect has a generation mechanism different from that of the Seebeck effect and is generated by the off-diagonal components of the thermoelectric tensor of the anomalous Nernst effect, the spin Seebeck effect, or the like.

For example, the first electromotive force V1 is represented by a quantity depending on a physical variable corresponding to the magnetic field of the off-diagonal components of the thermoelectric tensor of a thermoelectric conversion device 22. The first electromotive force V1 is antisymmetric with respect to the magnetic field, symmetric with respect to the in-plane component Jxy, and antisymmetric with respect to the perpendicular component Jz. The direction of the first electromotive force V1 is approximately perpendicular to the perpendicular component Jz.

The second electromotive force V2 is a thermoelectromotive force generated by a second thermoelectric conversion effect based on the in-plane component Jxy parallel to the placement surface 212 of the temperature gradient J1. The second thermoelectric conversion effect has a generation mechanism different from that of the first thermoelectric conversion effect and is generated by the diagonal components of the thermoelectric tensor of the Seebeck effect or the like. For example, the second electromotive force V2 is represented by a quantity depending on a physical variable corresponding to the temperature gradient J1 of the diagonal components of the thermoelectric tensor of a thermoelectric conversion device 22. The quantity of the second electromotive force V2 is a quantity antisymmetric to the temperature gradient. The direction of the second electromotive force V2 is approximately parallel to the direction of the in-plane component Jxy. If the in-plane component Jxy is parallel to the direction of the first electromotive force V1, the direction of the second electromotive force V2 is approximately parallel to the direction of the first electromotive force V1.

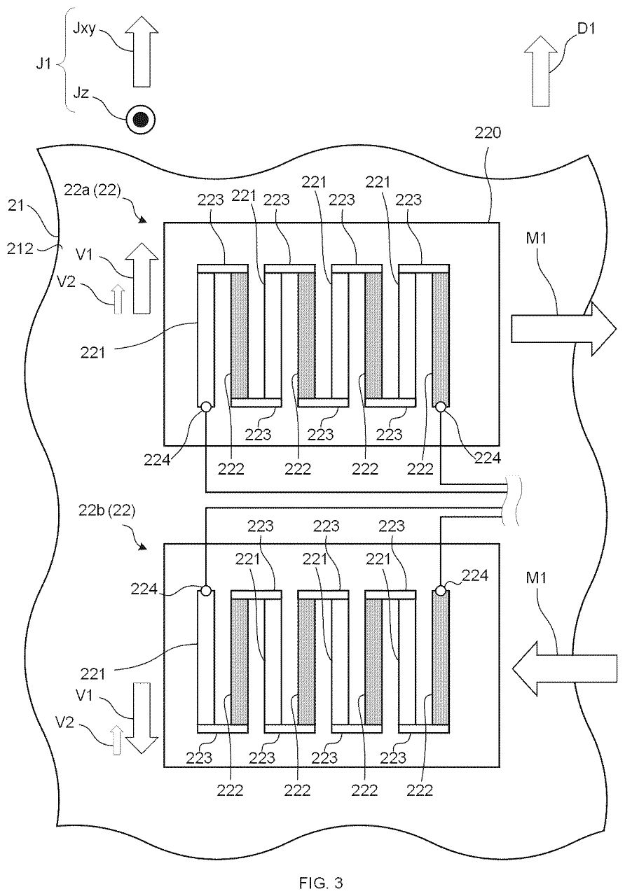

The first thermoelectric conversion devices 22a and the second thermoelectric conversion devices 22b are disposed on the single placement surface 212. At least one of the thermoelectric conversion devices 22 closest to each first thermoelectric conversion device 22a on the placement surface 212 is a second thermoelectric conversion device 22b. In the present embodiment, the first thermoelectric conversion devices 22a and the second thermoelectric conversion devices 22b are disposed alternately in a first direction D1. The first direction D1 is a direction along the placement surface 212 and is perpendicular to the direction in which the perpendicular component Jz is transmitted. This allows for, for example, a reduction in measurement errors caused by fluctuations in the in-plane component Jxy on the placement surface 212. In FIG. 3, the first direction D1 is parallel to the direction in which the in-plane component Jxy is transmitted. In the present embodiment, the first thermoelectric conversion devices 22a and the second thermoelectric conversion devices 22b are disposed on the single substrate 21. This means that it is easy to mount the first thermoelectric conversion devices 22a and the second thermoelectric conversion devices 22b. Note that the first thermoelectric conversion devices 22a and the second thermoelectric conversion devices 22b may be disposed on the substrate 21 in any form. For example, the first thermoelectric conversion devices 22a and the second thermoelectric conversion devices 22b may be disposed on different substrates 21. The thermoelectric conversion devices 22 may be electrically insulated from each other. For example, the first thermoelectric conversion devices 22a and the second thermoelectric conversion devices 22b may be electrically insulated from each other. This suppresses fluctuations in the thermoelectromotive forces V from the thermoelectric conversion devices 22 due to noise. The first thermoelectric conversion devices 22a may be connected in series. Similarly, the second thermoelectric conversion devices 22b may be connected in series. This increases the first electromotive force V1 and second electromotive force V2 included in the total thermoelectromotive force V of the multiple thermoelectric conversion devices 22 connected in series. Moreover, the first thermoelectric conversion devices 22a and the second thermoelectric conversion devices 22b may be connected in series.

### 1.2. Example of Thermoelectric Conversion Devices 22

This section describes an example of the above thermoelectric conversion devices 22. FIG. 3 is a diagram showing an example of a first thermoelectric conversion device 22a and a second thermoelectric conversion device 22b. As shown in FIG. 3, the first thermoelectric conversion device 22a and second thermoelectric conversion device 22b each include multiple thermoelectric conversion elements 221. The first thermoelectric conversion device 22a and second thermoelectric conversion device 22b according to the present embodiment may each further include an insulating substrate 220, first conductors 222, second conductors 223, and at least a pair of measuring terminals 224.

### <Insulating Substrate 220>

Each insulating substrate 220 is disposed on the placement surface 212 to insulate the object OB1 to be measured and the thermoelectric conversion elements 221 from each other. The insulating substrate 220 is smaller in size than the placement surface 212 of the substrate 21. The insulating substrate 220 may be integrally formed with the substrate 21. The substrate 21 and insulating substrates 220 may have any configuration, as long as the object OB1 to be measured is insulated from the thermoelectric conversion elements 221, first conductors 222, second conductors 223, and measuring terminals 224 (to be discussed later) and the heat of the object OB1 to be measured flows to the thermoelectric conversion elements 221. For example, the insulating substrates 220 may be provided as insulating layers on the placement surface 212.

### <Thermoelectric Conversion Elements 221>

The thermoelectric conversion elements 221 are each formed to extend in the direction in which the first electromotive force V1 is generated. Specifically, the thermoelectric conversion elements 221 extend in the direction in which the anomalous Nernst effect based on the perpendicular component Jz is generated to the greatest degree. The thermoelectric conversion elements 221 according to the present embodiment extend linearly along the direction in which the first electromotive force V1 is generated. The thermoelectric conversion elements 221 do not have to have such a shape and may include, for example, a curved portion. The direction in which the thermoelectric conversion elements 221 of the first thermoelectric conversion device 22a extend is approximately parallel to the direction in which the thermoelectric conversion elements 221 of the second thermoelectric conversion device 22b extend. This reduces the discrepancy between the first electromotive forces V1 generated by the first thermoelectric conversion device 22a and second thermoelectric conversion device 22b due to the anomalous Nernst effect based on the perpendicular component Jz. This facilitates separation of the contributions of the first electromotive force V1 and second electromotive force V2 included in each thermoelectromotive force V. The number of thermoelectric conversion elements 221 included in the first thermoelectric conversion device 22a is equal to the number of thermoelectric conversion elements 221 included in the second thermoelectric conversion device 22b and is four in the present embodiment. Note that the number of thermoelectric conversion elements 221 included in one thermoelectric conversion device 22 is not limited to four and may be any number. The first thermoelectric conversion device 22a and second thermoelectric conversion device 22b may include different numbers of thermoelectric conversion elements 221. In short, it is only necessary that the discrepancy between the second electromotive force V2 generated by one first thermoelectric conversion device 22a and the second electromotive force V2 generated by one second thermoelectric conversion device 22b be smaller than required measurement accuracy.

### <First Conductors 222, Second Conductors 223>

The first conductors 222 and second conductors 223 connect the first thermoelectric conversion device 22a in series so as to amplify the first electromotive forces V1 of the thermoelectric conversion elements 221 of the first thermoelectric conversion device 22a. Of the first conductors 222 and second conductors, the first conductors 222 are each disposed between two thermoelectric conversion elements 221 and extend in approximately the same direction as the direction in which the thermoelectric conversion elements 221 extend. Each second conductor 223 extends in a direction perpendicular to a first conductor 222 in the placement surface 212 such that it connects an end of a thermoelectric converter element 221 and an end of the first conductor 222. In this way, each thermoelectric conversion device 22 includes a meander structure in which the thermoelectric conversion elements 221 and the first conductors 222 are alternately disposed. Note that the first conductors 222 and second conductors 223 may connect the thermoelectric conversion elements 221 in any form. For example, one first conductor 222 and one second conductor 223 may connect ends of two adjacent thermoelectric conversion elements 221 such that the thermoelectric conversion elements 221 are linearly connected in series. In short, the conductors 222 and 223 only have to connect the thermoelectric conversion elements 221 included in each thermoelectric conversion device 22 so that the thermoelectromotive forces V generated by the thermoelectric conversion elements 221 reinforce each other. The conductors 222 and 223 may be mounted using any method such as sputtering of metal on the insulating substrate 220 or connection of conductors to ends of the thermoelectric conversion elements 221.

### <Measuring Terminals 224>

The measuring terminals 224 are configured to measure the thermoelectromotive forces V. Specifically, the measuring terminals 224 are configured to measure the thermoelectromotive forces V outputted from the thermoelectric conversion elements 221 connected in series by the first conductors 222 and second conductors 223. In the present embodiment, the measuring terminals 224 of the first thermoelectric conversion device 22a are electrically insulated from the measuring terminals 224 of the second thermoelectric conversion device 22b. The measuring terminals 224 of the first thermoelectric conversion device 22a are also electrically insulated from each other. This reduces the contact resistance of the thermoelectric conversion device 22 and improves the accuracy of measurement of the thermoelectromotive forces V. In the present embodiment, the measuring terminals 224 of the different thermoelectric conversion devices 22 are insulated from each other. The measuring terminals 224 may be physical connection terminals such as pins, tabs, or ribbon terminals, or virtual terminals serving as points at which the thermoelectromotive forces V are measured.

### <Port 23>

The port 23 allows the above thermoelectric conversion devices 22 to be electrically connected to an external device (not shown). In the present embodiment, the port 23 is electrically connected to the measuring terminals 224 of each thermoelectric conversion device 22. Any wiring may be interposed between each measuring terminal 224 and the port 23. By connecting the port 23 to the external device, information about the thermoelectromotive forces V outputted from the multiple thermoelectric conversion devices 22 (specifically, the measuring terminals 224) is transmitted to the external device. Thus, the external device can perform various processes on the basis of the thermoelectromotive forces outputted from the thermoelectric conversion system 2. The port 23 according to the present embodiment is formed to comprehensively receive wiring extending from each of the multiple measuring terminals 224. This makes the wiring for connecting with the external device simpler. For example, the port 23 is a multi-channel port capable of transmitting the thermoelectromotive forces V outputted from the measuring terminals 224 as independent signals. Note that the port 23 does not have to be such a port and may consist of multiple ports.

The physical property (specifically, the magnetism) of the above thermoelectric conversion elements 221 will be described below. The thermoelectric conversion elements 221 are each configured to generate the anomalous Nernst effect described above. The sign of the Nernst coefficient of the thermoelectric conversion elements 221 of the first thermoelectric conversion device 22a is different from that of the thermoelectric conversion elements 221 of the second thermoelectric conversion device 22b. In other words, the polarity of the thermoelectric conversion elements 221 of the first thermoelectric conversion device 22a is different from that of the thermoelectric conversion elements 221 of the second thermoelectric conversion device 22b. For this reason, the sign of the first electromotive forces V1 generated by the thermoelectric conversion elements 221 of the first thermoelectric conversion device 22a on the basis of a certain temperature gradient J1 is different from the sign of the first electromotive forces V1 generated by the thermoelectric conversion elements 221 of the second thermoelectric conversion device 22b on the basis of the same temperature gradient J1. On the other hand, the first electromotive forces V1 generated by the thermoelectric conversion elements 221 of the first thermoelectric conversion device 22a on the basis of this temperature gradient J1 and the second electromotive forces V2 generated by the thermoelectric conversion elements 221 of the second thermoelectric conversion device 22b on the basis of this temperature gradient J1 have the same signs. This is because the signs are defined by the direction of the in-plane component Jxy. Such opposite polarities related to the anomalous Nernst effect of the first thermoelectric conversion device 22a and second thermoelectric conversion device 22b can be achieved, for example, by reversing the polarity (for example, the direction of spontaneous magnetization) of the magnetic structure of the magnetic material contained in the thermoelectric conversion elements 221 or the sign of the Nernst coefficient specific to a material contained in the thermoelectric conversion elements 221.

The thermoelectric conversion elements 221 according to the present embodiment include the magnetic material having the magnetic structure capable of generating the anomalous Nernst effect. The magnetic structure may be an antiferromagnetic structure, a canted antiferromagnetic structure, a ferrimagnetic structure, or a ferromagnetic structure, as long as it is able to generate the anomalous Nernst effect. An antiferromagnetic magnetic order with spontaneous magnetization is also called a weak ferromagnetic structure. The magnetic structure of the magnetic material includes at least one of a first magnetic structure and a second magnetic structure formed to be time-reversal symmetric with respect to the first magnetic structure. The magnetic material of the thermoelectric conversion elements 221 of the first thermoelectric conversion device 22a is configured such that the ratio of a magnetic domain corresponding to the second magnetic structure to a magnetic domain corresponding to the first magnetic structure is greater than one. The magnetic material of the thermoelectric conversion elements 221 of the second thermoelectric conversion device 22b is configured such that the ratio of the magnetic domain corresponding to the second magnetic structure to the magnetic domain corresponding to the first magnetic structure is smaller than one. In other words, the sign of the components of the thermoelectric tensor corresponding to the anomalous Nernst effect generated by the first magnetic structure is different from the sign of the components of the thermoelectric tensor corresponding to the anomalous Nernst effect generated by the second magnetic structure. Thus, the thermoelectric conversion elements 221 of the second thermoelectric conversion device 22b are configured such that the sign of the first electromotive forces V1 generated by the thermoelectric conversion elements 221 is opposite to the sign of a temperature gradient in approximately the same direction as the direction of the temperature gradient J1 of the thermoelectric conversion elements 221 of the first thermoelectric conversion device 22a. In such a magnetic structure, spontaneous magnetization occurs along the easy axis of magnetization. If the magnetic material is a ferromagnetic material or ferrimagnetic material, the easy axis of magnetization is approximately parallel to the spin easy axis. If the magnetic material is a canted antiferromagnetic material, the easy axis of magnetization extends in a direction different from the spin easy axis (for example, a direction perpendicular to the spin easy axis). The magnetic structure of the first thermoelectric conversion device 22a differs in polarity from that of the second thermoelectric conversion device 22b. Therefore, the direction M1 of the magnetic domain of the first thermoelectric conversion device 22a is opposite to the direction M1 of the magnetic domain of the second thermoelectric conversion device 22b. In the present embodiment, the thermoelectric conversion elements 221 contain a ferrimagnetic material, and their easy axis of magnetization is along the placement surface 212. In other words, the easy axis of magnetization extends in a direction approximately parallel to the placement surface 212, which is different from the direction in which the thermoelectric conversion elements 221 extend.

The thermoelectric conversion elements 221 of the first thermoelectric conversion device 22a and the thermoelectric conversion elements 221 of the second thermoelectric conversion device 22b may contain any material as long as the material is able to generate the anomalous Nernst effect. For example, the thermoelectric conversion elements 221 of the first thermoelectric conversion device 22a and the thermoelectric conversion elements 221 of the second thermoelectric conversion device 22b may consist of approximately the same compositions capable of generating the anomalous Nernst effect. Examples of the compositions capable of generating the anomalous Nernst effect include Mn3Sn, Mn3Ge, Mn3Ga, Co2MnGa, Fe3Al, Fe3Ga, Fe2Sn, or alloys, elemental substitutes, or mixtures thereof. Any mechanism may be used as the anomalous Nernst effect generation mechanism. One example is a mechanism originating from an antiferromagnetic magnetic structure with a non-collinear spin structure. Such a mechanism tends to have a larger Nernst coefficient than other generation mechanisms. This allows for more precise measurement, downsizing of the device, and the like. The thermoelectric conversion elements 221 may be embodied as polycrystals or single crystals of the above materials. It is only necessary that the crystallographic domain of the single crystals be uniform to the extent that asymmetric physical properties due to a symmetry reduction associated with the generation of a magnetic order are observed. The thermoelectric conversion elements 221 according to the present embodiment are formed as thin films having a thickness in a direction perpendicular to the placement surface 212. Forming the thermoelectric conversion elements 221 as thin films makes the contribution of magnetic anisotropy greater than that of other factors. This makes the easy axis of magnetization and the spin easy axis more likely to extend in a direction along the placement surface 212. Thus, it becomes easy to properly adjust the direction of the first electromotive force V1 generated by the anomalous Nernst effect. The thickness of the thermoelectric conversion elements 221 may be any thickness. Specifically, for example, the thickness may be 5, 6, 7, 8, 9, 10, 20, 30, 40, 50, 60, 70, 80, 90, 100, 200, 300, 400, 500, 600, 700, 800, or 900 nm or may be in the range between any two of the values illustrated above. Note that the thickness may fall outside such ranges. The thermoelectric conversion elements 221 may be mounted on the insulating substrate 220 using an any method. Examples of the mounting method include physical vapor deposition such as sputtering and ion plating, plating, chemical vapor deposition, molecular beam epitaxial growth (MBE), sintering of the powder of the above compounds, various types of printing such as inkjet printing using liquid drops obtained by dissolving the above compounds, and printing using droplets of the above compounds, and three-dimensional printing using the above compounds. The thermoelectric conversion elements 221 may be mounted using a method similar to the method for mounting the first conductors 222 and the second conductors 223. This simplifies the production process. The thermoelectric conversion elements 221 included in one thermoelectric conversion device 22 may contain the same magnetic material or different magnetic materials.

In the thermoelectric conversion system 2 thus configured, when the thermoelectromotive force V generated by the first thermoelectric conversion device 22a on the basis of a certain temperature gradient J1 is +V1+V2, the thermoelectromotive force V generated by the second thermoelectric conversion device 22b on the basis of the same temperature gradient J1 is −V1+V2. In other words, the direction of the first electromotive force V1 generated by the anomalous Nernst effect is reversed. For this reason, by comparing the thermoelectromotive force V of the first thermoelectric conversion device 22a and the thermoelectromotive force V of the second thermoelectric conversion device 22b, the components of each thermoelectromotive force V based on the temperature gradient J1, such as the first electromotive force V1 and second electromotive force V2, can be separated more accurately. In particular, the first electromotive force V1 can be measured more accurately. This allows for construction of a measuring system 1 capable of acquiring various types of information originating from heat more accurately.

### 1.3. Modification of Thermoelectric Conversion System 2

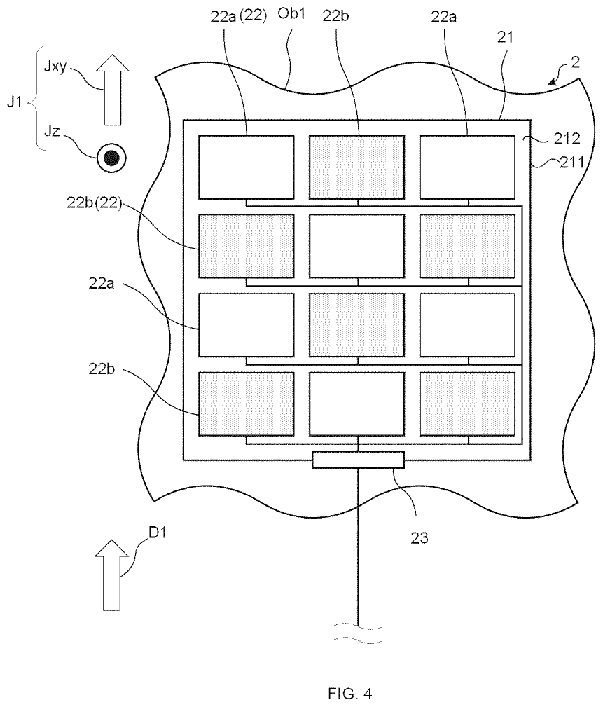

Next, a modification of the above thermoelectric conversion devices 22 will be described. FIGS. 4 to 6 are diagrams showing a modification of the thermoelectric conversion devices 22. The above embodiment and the following modification can be combined as appropriate.

As shown in FIG. 4, first thermoelectric conversion devices 22a and second thermoelectric conversion devices 22b may be disposed alternately on a placement surface 212 in a first direction D1 and also along another direction from the first direction D1. Note that the first thermoelectric conversion devices 22a and second thermoelectric conversion devices 22b do not have to be disposed alternately and two or more thermoelectric conversion devices 22 of the same type may be disposed adjacent to each other. In short, the thermoelectric conversion devices 22 may be disposed in any form, as long as the thermoelectric conversion devices 22 include at least one first thermoelectric conversion device 22a and at least one second thermoelectric conversion device 22b.

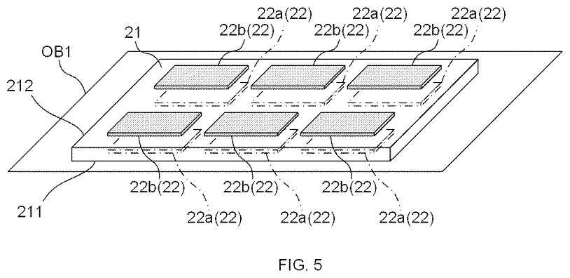

First thermoelectric conversion devices 22a and second thermoelectric conversion devices 22b may be disposed on different surfaces. For example, as shown in FIG. 5, first thermoelectric conversion devices 22a may be disposed on a contact surface 211, and second thermoelectric conversion devices 22b may be disposed on a placement surface 212. In this case, the contact surface 211 can also be said to be a second placement surface on which the first thermoelectric conversion devices 22a are disposed. In this case, the first thermoelectric conversion devices 22a and the second thermoelectric conversion devices 22b may be located in opposite positions with the substrate 21 therebetween in the thickness direction of the substrate 21. This suppresses variations in the thermoelectromotive force V due to variations in the inflow of heat. Note that it is preferable to dispose the first thermoelectric conversion devices 22a on the contact surface 211 such that the heat of the object OB1 to be measured is transferred to them and they are insulated from the object OB1 to be measured. For example, the second thermoelectric conversion devices 22b may be covered by a protective member having electrical insulation properties.

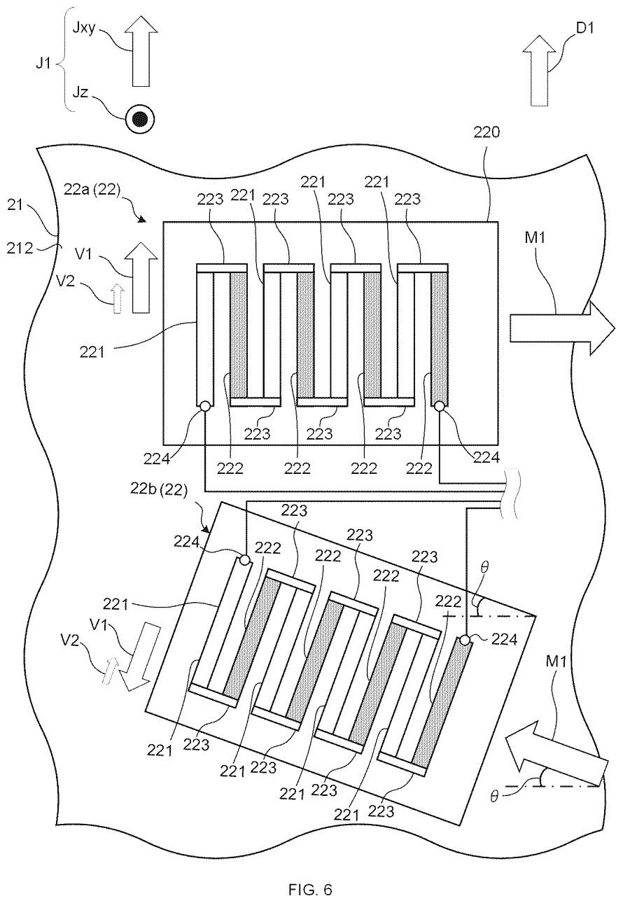

As shown in FIG. 6, the thermoelectric conversion elements 221 of a first thermoelectric conversion device 22a and the thermoelectric conversion elements 221 of a second thermoelectric conversion device 22b do not have to extend in the same direction. For example, the thermoelectric conversion elements 221 of the second thermoelectric conversion device 22b may be disposed so as to be inclined with respect to the thermoelectric conversion elements 221 of the first thermoelectric conversion device 22a by an angle θ. In this case, the direction M1 of the magnetic domain of the second thermoelectric conversion device 22b is inclined with respect to the direction M1 of the magnetic domain of the thermoelectric conversion elements 221 by the angle θ. Therefore, the thermoelectric conversion elements 221 of the second thermoelectric conversion device 22b are inclined with respect to the temperature gradient J1 along the thermoelectric conversion elements 221 of the first thermoelectric conversion device 22a by the angle θ. Thus, the temperature gradients of the thermoelectric conversion elements 221 of the second thermoelectric conversion device 22b become substantially a temperature gradient J1 cos θ. For this reason, when the thermoelectromotive force V generated by the first thermoelectric conversion device 22a on the basis of the certain temperature gradient J1 is V1+V2, the thermoelectromotive force V generated by the second thermoelectric conversion device 22b on the basis of the temperature gradient J1 becomes (−V1+V2)cos θ. Such information on the angle θ is previously prepared. Thus, by comparing the thermoelectromotive force V of the first thermoelectric conversion device 22a and the thermoelectromotive force V of the second thermoelectric conversion device 22b, various components included in each thermoelectromotive force V, such as the first electromotive force V1 and second electromotive force V2, can be separated.

When the thermoelectric conversion elements 221 of the first thermoelectric conversion device 22a and the thermoelectric conversion elements 221 of the second thermoelectric conversion device 22b have different thermoelectric coefficients, the values of the thermoelectromotive forces V obtained from the first thermoelectric conversion device 22a and the second thermoelectric conversion device 22b can be corrected on the basis of the difference between the thermoelectric coefficients. Thus, the thermoelectromotive forces V can be compared.

### 2. Another Example of Measuring system 1

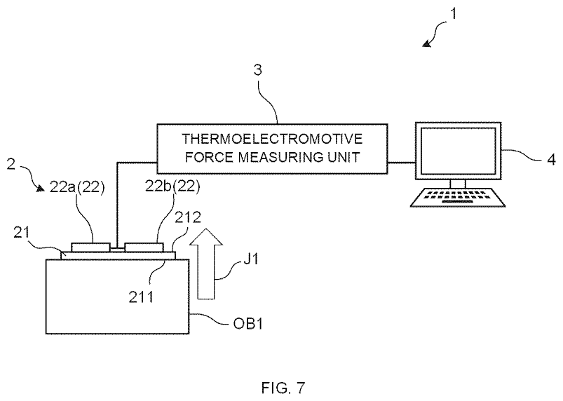

This section describes another example of the above measuring system 1. FIG. 7 is a diagram showing an overview of another example of the measuring system 1. The measuring system 1 according to the present embodiment includes the above thermoelectric conversion system 2, as well as a thermoelectromotive force measuring unit 3 and a user terminal 4 as external devices.

### 2.1. External Devices

### <Thermoelectromotive Force Measuring Unit 3>

The thermoelectromotive force measuring unit 3 is configured to measure the thermoelectromotive forces V of the first thermoelectric conversion devices 22a and the thermoelectromotive forces V of the second thermoelectric conversion devices 22b. The thermoelectromotive force measuring unit 3 may include, for example, a voltmeter capable of measuring the respective thermoelectromotive forces V. The thermoelectromotive force measuring unit 3 may include multiple channels for measuring the thermoelectromotive forces V of the first thermoelectric conversion devices 22a and the second thermoelectric conversion devices 22b. Note that the thermoelectromotive force measuring unit 3 does not have to include the voltmeter and may include any other type of measuring instrument, such as an ammeter or LCR meter.

### <User Terminal 4>

The user terminal 4 is configured to perform various types of information processing (to be discussed later) on the basis of the measurement results obtained by the thermoelectromotive force measuring unit 3. Details of the user terminal 4 will be described later along with the information processing.

### 2.2. Hardware Configuration of User Terminal 4

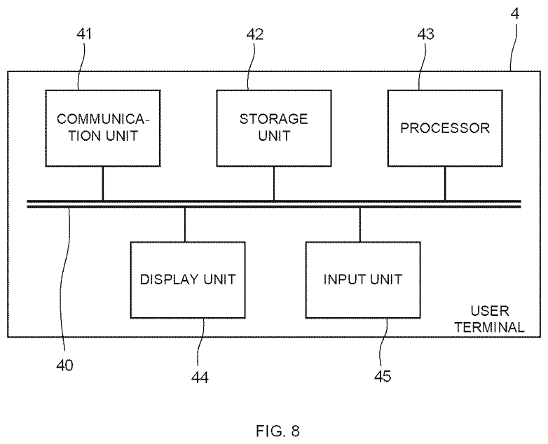

This section describes an example of the hardware configuration of the user terminal 4. FIG. 8 is a block diagram showing the hardware configuration of the user terminal 4. The user terminal 4 includes a communication bus 40, a communication unit 41, a storage unit 42, a processor 43, a display unit 44, and an input unit 45. These components are electrically connected through the communication bus 40 in the user terminal 4.

### <Communication Unit 41>

While the communication unit 41 preferably uses wired communication means such as USB, IEEE 1394, Thunderbolt®, or wired LAN network communication, it may use wireless LAN network communication, mobile communication such as 3G/LTE/5G, BLUETOOTH® communication, or the like as necessary. That is, the communication unit 41 preferably is able to use the set of these multiple communication means. In other words, the user terminal 4 may transmit and receive various types of information to and from the outside through the communication unit 41 and any network.

### <Storage Unit 42>

The storage unit 42 is storing various types of information defined by the foregoing description. The storage unit 42 may be embodied, for example, as a storage device such as a solid-state drive (SSD) for storing various programs or the like related to the user terminal 4 executed by the processor 43, or as memory such as random access memory (RAM) for storing temporarily required information (arguments, arrays, etc.) related to program calculations. The storage unit 42 is storing various programs, variables, and the like related to the user terminal 4 executed by the processor 43.

### <Processor 43>

The processor 43 processes and controls overall operation related to the user terminal 4. The processor 43 is, for example, a central processing unit (CPU) (not shown). The processor 43 implements various functions related to the user terminal 4 by reading a predetermined program stored in the storage unit 42. That is, when information processing by software stored in the storage unit 42 is specifically executed by the processor 43, which is an example of hardware, functional units included in the processor 43 are implemented. These will be described in more detail in the next section. Note that the processor 43 does not have to be a single processor and may be embodied as function-specific multiple processors 43. Or, the processor 43 may be a combination of these.

### <Display Unit 44>

The display unit 44 may be contained in the housing of the user terminal 4 or may be externally attached thereto. The display unit 44 displays a graphical user interface (GUI) screen operable by a user. It is preferable to select a display device such as a CRT display, a liquid crystal display, an organic EL display, or a plasma display as the display unit 44 in accordance with the type of user terminal 4.

### <Input Unit 45>

The input unit 45 may be contained in the housing of the user terminal 4 or may be externally attached thereto. For example, the input unit 45 may be embodied as a touchscreen integrated with the display unit 44. If the input unit 45 is a touchscreen, the user can make inputs by performing a tap operation, a swipe operation, or the like thereon. Of course, the input unit 45 may be a switch button, mouse, QWERTY keyboard, or the like in place of a touchscreen. That is, the input unit 45 receives inputs made by the user. The inputs are transferred to the processor 43 as instruction signals through the communication bus 40, and the processor 43 performs predetermined control or calculation as necessary.

### 2.3. Functional Configuration of User Terminal 4

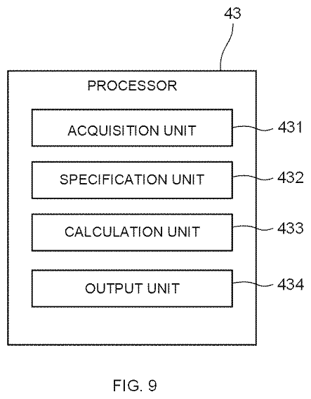

This section describes an example of the functional configuration of the above processor 43. FIG. 9 is a diagram showing an example of the functional units included in the processor 43. The processor 43 includes an acquisition unit 431, a specification unit 432, a calculation 433, and an output unit 434.

### <Acquisition Unit 431>

The acquisition unit 431 is configured to acquire information from the thermoelectromotive force measuring unit 3 or any other device. For example, the acquisition unit 431 is configured to acquire the respective thermoelectromotive forces V of the thermoelectric conversion devices 22 through the thermoelectromotive force measuring unit 3. The acquisition unit 431 is also configured to acquire various types of information by reading various types of information stored in a storage area, which is at least a part of the storage unit 42, and writing the read information into a work area, which is at least a part of the storage unit 42. The storage area is, for example, an area of the storage unit 42 embodied as a storage device such as SSD. The work area is an area embodied as memory such as RAM.

### <Specification Unit 432>

The specification unit 432 is configured to receive specification from the user, any other functional unit, or any other device. For example, the specification unit 432 receives specification based on an input made to the input unit 45.

### <Calculation Unit 433>

The calculation unit 433 is configured to perform various calculations on the basis of various types of information, such as information acquired by the acquisition section 431 and specification received by the specification unit 432. For example, the calculation unit 433 calculates the first electromotive force V1 or the second electromotive force V2 on the basis of the thermoelectromotive force V acquired by the acquisition unit 431.

### <Output Unit 434>

The output unit 434 is configured to output various types of information. An external device (not shown) can perform various types of control on the basis of the information outputted from the output unit 434. For example, an external device may estimate the temperature of the object OB1 to be measured on the basis of information outputted from the output unit 434 and control the driving mode of the object OB1 to be measured on the basis of the estimated temperature. This information can be presented to the user through the display unit 34 of the user terminal 4 or any other device. In this case, for example, the output unit 434 controls the display unit 34 of the user terminal 4 so that visual information such as a screen, images including still or moving images, icons, or messages are displayed on the display unit 34. The output unit 434 may generate only rendering information for displaying visual information on the user terminal 4. The output unit 434 may present the outputted information to the user not through the user terminal 4 or any other device.

### 2.4. Information Processing Performed By Measuring system 1

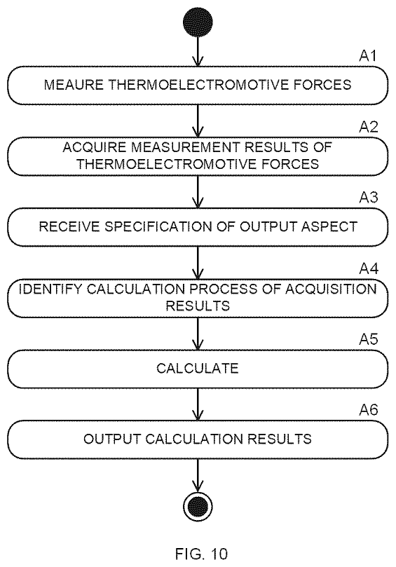

This section describes information processing performed by the above measuring system 1. FIG. 10 is an activity diagram showing an example of the flow of information processing performed by the measuring system 1. The information processing may include any exception handling (not shown). The exception handling includes the interruption of the information processing and the omission of each process. Selection or input in the information processing may be performed on the basis of a user operation, or automatically without depending on a user operation.

### [Activity A1]

First, in activity A1, the thermoelectromotive force measuring unit 3 measures the thermoelectromotive forces V outputted from the thermoelectric conversion system 2. Thus, the thermoelectromotive force measuring unit 3 acquires the thermoelectromotive forces V of the first thermoelectric conversion devices 22a and the second thermoelectric conversion devices 22b included in the thermoelectric conversion system 2. The thermoelectromotive force measuring unit 3 then outputs the obtained results to the user terminal 4. In the present embodiment, the thermoelectromotive force measuring unit 3 outputs the measured values themselves of the thermoelectromotive forces V of the first thermoelectric conversion devices 22a and second thermoelectric conversion devices 22b. Note that the thermoelectromotive force measuring unit 3 may output the thermoelectromotive forces V in any form. For example, the thermoelectromotive force measuring unit 3 may output the average value of the thermoelectromotive forces V of the first thermoelectric conversion devices 22a and the average value of the thermoelectromotive forces V of the second thermoelectric conversion devices 22b. In short, the thermoelectromotive force measuring unit 3 only has to output the measurement results such that the thermoelectromotive forces V corresponding to the first thermoelectric conversion devices 22a and the thermoelectromotive forces V corresponding to the second thermoelectric conversion devices 22b can be distinguished from each other. In the present embodiment, the thermoelectromotive force measuring unit 3 outputs the thermoelectromotive forces V of the first thermoelectric conversion devices 22a, which are each V1+V2, and the thermoelectromotive forces V of the second thermoelectric conversion devices 22b, which are each −V1+V2, as the measurement results.

### [Activity A2]

The process then proceeds to activity A2. The acquisition unit 431 acquires the thermoelectromotive forces V of the first thermoelectric conversion devices 22a and the thermoelectromotive forces V of the second thermoelectric conversion devices 22b measured by the thermoelectromotive force measuring unit 3 in activity A1. The thermoelectromotive forces V acquired by the thermoelectromotive force measuring unit 3 are not limited to the thermoelectromotive forces V themselves outputted from the measuring terminals 224 and may be the values obtained by subjecting the thermoelectromotive forces V measured by the thermoelectromotive force measuring unit 3 to the above arbitrary process.

### [Activity A3]

The process then proceeds to activity A3. The specification unit 432 receives specification of at least one of a first voltage value and a second voltage value.

### <First Voltage Value>

The first voltage value is a value calculated such that the second electromotive forces V2 of the first thermoelectric conversion devices 22a and the second electromotive forces V2 of the second thermoelectric conversion devices 22b included in the thermoelectromotive forces V acquired in activity A2 cancel out each other. Note that each voltage value is not limited to the value itself of a voltage and may be a value uniquely corresponding to the voltage, such as the value of a current flowing through a certain resistor or power consumption.

### <Second Voltage Value>

The second voltage value is a value calculated such that the first electromotive forces V1 of the first thermoelectric conversion devices 22a and the first electromotive forces V1 of the second thermoelectric conversion devices 22b included in the acquired thermoelectromotive forces V cancel out each other. A method for calculating these voltage values will be described later.

### [Activity A4]

The process then proceeds to activity A4. The specification unit 432 receives specification related to the voltage values from the outside. For example, the specification unit 432 receives specification of at least one of the first and second voltage values from the user.

### [Activity A5]

The process then proceeds to activity A5. The calculation unit 433 calculates the value corresponding to the specification received in activity A4 of the first and second voltage values on the basis of the thermoelectromotive forces V of the first thermoelectric conversion devices 22a and the thermoelectromotive forces V of the second thermoelectric conversion devices 22b acquired in activity A2 and the specification received in activity A4. For example, if the first voltage value is specified, the calculation unit 433 subtracts the thermoelectromotive forces V=−V1+V2 of the second thermoelectric conversion devices 22b from the thermoelectromotive forces V=V1+V2 of the first thermoelectric conversion devices 22a and divides the subtraction results by 2. In this way, the calculation unit 433 calculates the value of V1 as the first voltage value. If the second voltage value is specified, the calculation unit 433 adds the thermoelectromotive forces V =−V1+V2 of the second thermoelectric conversion devices 22b to the thermoelectromotive forces V=V1+V2 of the first thermoelectric conversion devices 22a and divides the addition results by 2. In this way, the calculation unit 433 calculates the value of V2 as the second voltage value. If the first thermoelectric conversion devices 22a are inclined with respect to the second thermoelectric conversion devices 22b as described above, the calculation unit 433 may correct the value of the thermoelectromotive forces V on the basis of the angle θ of the inclination and then perform the above addition or subtraction. Note that the calculation unit 433 may calculate these voltage values not in accordance with any specification.

### [Activity A6]

The process then proceeds to activity A6. The output unit 434 outputs the calculation results obtained in activity A5. In the present embodiment, the output unit 434 outputs the voltage value corresponding to the specification received in activity A4. For example, if the specification unit 432 receives specification of the first voltage value in activity A4, the output unit 434 outputs the first voltage value. In the present embodiment, the output unit 434 outputs the first electromotive force V1 as the first voltage value. If the specification unit 432 receives specification of the second voltage value in activity A4, the output unit 434 outputs the second voltage value. In the present embodiment, the output unit 434 outputs the second electromotive force V2 as the second voltage value.

The voltage value thus outputted is used, for example, to control an external device. These voltage values correspond to the in-plane component Jxy and the perpendicular component Jz of the temperature gradient J1 and therefore contain information related to the temperature of the object OB1 to be measured and variations in the temperature. For this reason, the outputted voltage value can be used particularly to perform control according to the temperature of the object OB1 to be measured.

### 3. Method for producing Measuring System 1

This section describes a method for producing the above measuring system 1.

### 3.1. Flow of Process of Producing Measuring System 1

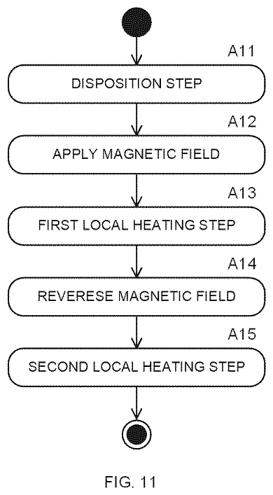

FIG. 11 is an activity diagram showing the flow of the process of producing the measuring system 1.

### [Activity A11]

First, in activity A11, a disposition step is performed. In the disposition step, the precursors 22c of the thermoelectric conversion devices 22 each including the thermoelectric conversion elements 221 are disposed on the placement surface 212. The precursors 22c are the precursors of the thermoelectric conversion devices 22 and become first thermoelectric conversion devices 22a and second thermoelectric conversion devices 22b by aligning domains such as the magnetic domains.

### [Activity A12]

The process then proceeds to activity A12. An external magnetic field H1 is applied to the precursors 22c. The application of the external magnetic field H1 is performed, for example, by energizing an electromagnet or moving a ferromagnetic material. The external magnetic field H1 is one of various types of energy supplied to the precursors 22c. The external magnetic field H1 is applied at least in a direction approximately perpendicular to both the direction in which the first electromotive force V1 is generated and a direction perpendicular to the placement surface 212 (for example, in a direction along the placement surface 212).

### [Activity A13]

The process then proceeds to activity A13. A first local heating step is performed. In the first local heating step, energy is locally supplied to portions of the thermoelectric conversion elements 221 of the precursors 22c disposed in activity A11. Thus, the magnetic domains included in the thermoelectric conversion elements 221 (specifically, the directions M1 of the magnetic domains) are aligned. In the present embodiment, the local energy supply includes local heating to the thermoelectric conversion elements 221. Specifically, heat is locally applied to the thermoelectric conversion elements 221 using a laser. Thus, the temperature of the locally heated portions of the thermoelectric conversion elements 221 reaches a predetermined heating temperature. The heating temperature is, for example, near or equal to or higher than the magnetic transition point of the magnetic material contained in the thermoelectric conversion elements 221. The heating temperature is not limited to such a temperature and may be set properly in accordance with the magnitude of the external magnetic field H1 or the materials contained in the thermoelectric conversion elements 221. The local heating does not have to be performed using a laser and may be performed using any other method, such as induction heating or movement of a heating element. After the local heating is performed in the external magnetic field H1, the precursors 22c are cooled. Thus, due to the contribution of the external magnetic field H1, the directions M1 of the magnetic domains of the precursors 22c are aligned. In this way, the precursors 22c become first thermoelectric conversion devices 22a.

### [Activity A14]

The process then proceeds to activity A14. The direction of the external magnetic field H1 is reversed. The reversal of the direction of the external magnetic field H1 is performed, for example, by reversing the direction in which the electromagnet is energized.

### [Activity A15]

The process then proceeds to activity A15. A second local heating step is performed. In the second local heating step, energy is locally supplied to the thermoelectric conversion elements 221 of the precursors 22c disposed in activity A11. Thus, the magnetic domains included in the thermoelectric conversion elements 221 (specifically, the directions M1 of the magnetic domains) are aligned. At this time, due to the reversal of the direction of the external magnetic field H1 in activity A14, the external magnetic field H1 is applied to the precursors 22c of the second thermoelectric conversion devices 22b in a direction opposite to the direction of the external magnetic field H1 applied to the precursors 22c of the first thermoelectric conversion devices 22a.

### 3.2. Example of Local Heating

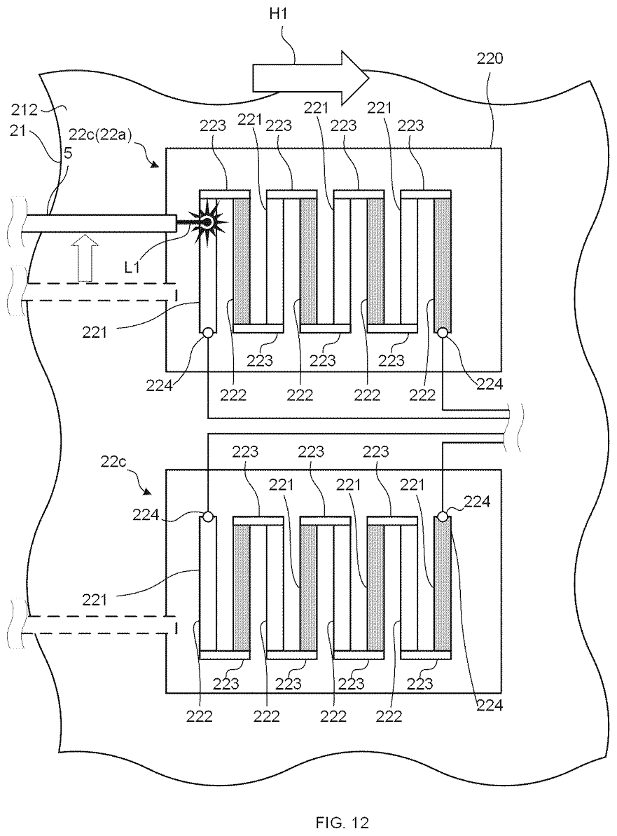

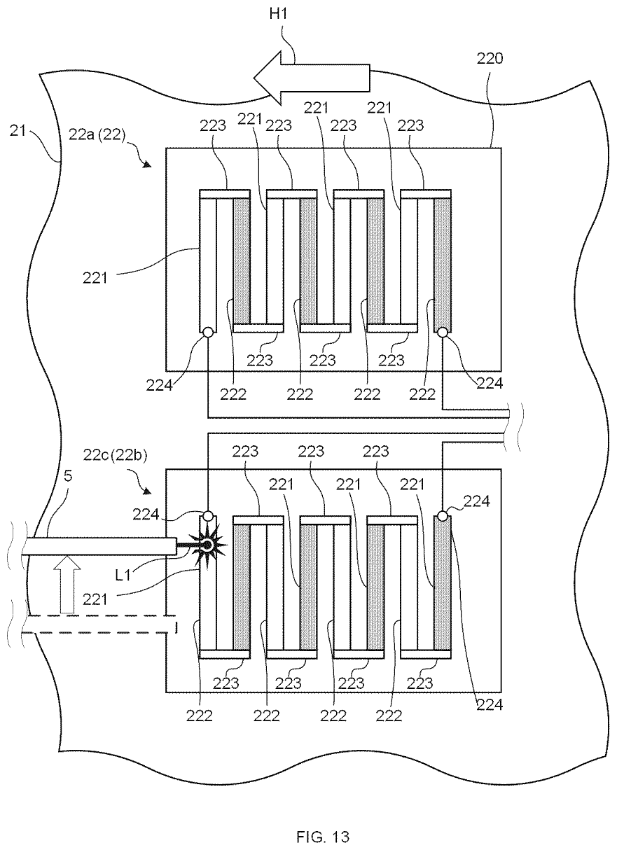

This section describes an example of the local heating in activity A13 and activity A15. FIGS. 12 and 13 are diagrams showing an example of local heating using a laser.

As shown in FIG. 12, in the first local heating step in activity A13, the external magnetic field H1 is being applied in a direction approximately parallel to the directions M1 of the magnetic domains of the precursors 22c of the first thermoelectric conversion devices 22a. The local heating facilitates alignment of the directions M1 of the magnetic domains with the direction of the external magnetic field H1. A laser irradiation device 5 irradiates a precursor 22c to which the external magnetic field H1 is being applied in this manner, with a laser L1. The laser L1 may be any type of laser as long as it includes a wavelength absorbable by the thermoelectric converter elements 221. The range of each thermoelectric conversion element 221 of the precursor 22c irradiated with the laser L1 is moved by moving the laser irradiation device 5 along the thermoelectric conversion element 221. Thus, a portion of the thermoelectric conversion element 221 being irradiated with the laser L1 is heated, and a portion of the thermoelectric conversion element 221 that has been heated and then fallen outside the laser L1 irradiation range is cooled from a locally heated state. When the temperature of the thermoelectric conversion elements 221 falls below the magnetic transition point due to this cooling, a magnetic order is generated in the thermoelectric conversion element 221. The direction M1 of the magnetic domain of the magnetic order is aligned by the external magnetic field H1. In this way, the precursor 22c becomes a first thermoelectric conversion device 22a. Such local heating using the laser L1 is performed on each of the other precursors 22c to be converted into first thermoelectric conversion devices 22a.

Subsequently, as shown in FIG. 13, the direction of the external magnetic field H1 is reversed in activity A14 and then the second local heating step is performed in activity A15. The specific operation of the laser irradiation device 5 is similar to that in the first local heating step. As described above, the external magnetic field H1 is applied to the precursors 22c of the second thermoelectric conversion devices 22b in a direction opposite to the direction of the external magnetic field H1 applied to the precursors 22c of the first thermoelectric conversion devices 22a. For this reason, the precursors 22c heated in the second local heating step are more likely to become second thermoelectric conversion devices 22b than the first thermoelectric conversion devices 22a. As seen above, by controlling the directions M1 of the magnetic domains by the reversal of the direction of the external magnetic field H1, the first thermoelectric conversion devices 22a and second thermoelectric conversion devices 22b are generated from the precursors 22c.

Note that the local energy supply is not limited to the local heating using the laser L1 or the like with the external magnetic field H1 being applied. For example, the local energy supply may be performed by locally applying, to each thermoelectric conversion device 22, an external magnetic field H1 having a magnetic strength equal to or greater than the coercive force of the magnetic material contained in the thermoelectric conversion elements 221 of the thermoelectric conversion device 22. In short, it is only necessary to locally supply energy required to align the magnetic domains, to each thermoelectric conversion device 22.

As seen above, by locally supplying energy to the multiple precursors 22c disposed on the substrate 21 and aligning the directions M1 of the magnetic domains with the desired direction, one of first thermoelectric conversion devices 22a and second thermoelectric conversion devices 22b are generated from the precursors 22c. Thus, the process of producing the precursor of the thermoelectric conversion system 2 including the precursors 22c and the process of producing the thermoelectric conversion system 2 including the first thermoelectric conversion devices 22a and second thermoelectric conversion devices 22b from the precursor of the thermoelectric conversion system 2 can be separated. Such separation of the production processes allows for more efficient production of the thermoelectric conversion system 2.

### 4. Others

The aspects of the above measuring system 1 and the like are only illustrative and are not limiting.

The above thermoelectric conversion devices 22 may be formed by connecting thermoelectric conversion elements 221 having different polarities in series. Thus, the first electromotive forces V1 of the thermoelectric conversion elements 221 having the different polarities reinforce each other. This further facilitates acquisition of information about heat exchange with the object OB1 to be measured. Hereafter, for convenience's sake, thermoelectric conversion elements 221 having a certain polarity included in each thermoelectric conversion device 22 are referred to as thermoelectric conversion elements 221a, and thermoelectric conversion elements 221 having a polarity different from that of the thermoelectric conversion elements 221a included in the thermoelectric conversion device 22 as thermoelectric conversion elements 221b. The polarity of the thermoelectric conversion elements 221a of a first thermoelectric conversion device 22a and the polarity of the thermoelectric conversion elements 221a of a second thermoelectric conversion device 22b are different, and the polarity of the thermoelectric conversion elements 221b of the first thermoelectric conversion device 22a and the polarity of the thermoelectric conversion elements 221b of the second thermoelectric conversion device 22b are different.

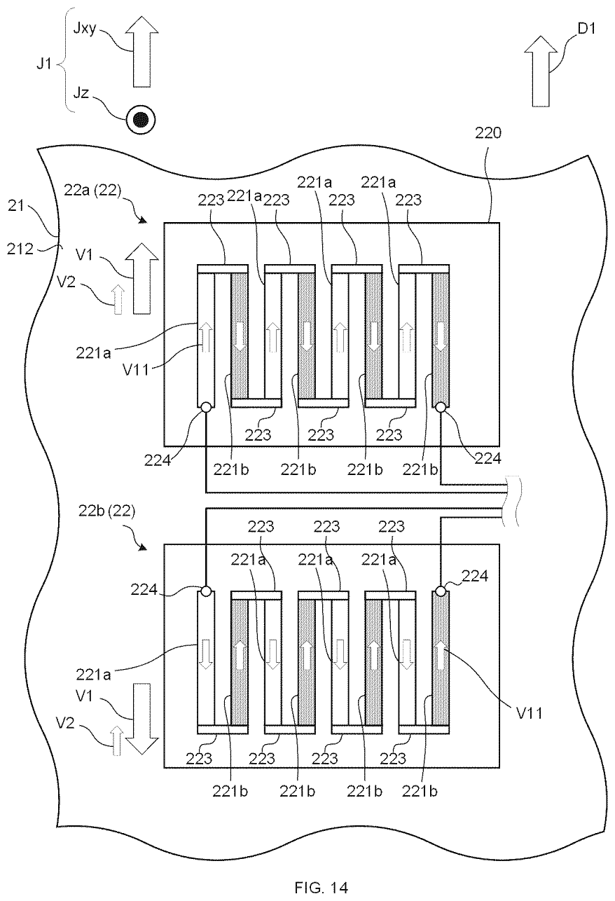

FIG. 14 is a diagram showing a modification of the thermoelectric conversion devices 22. Arrows V11 shown in thermoelectric conversion elements 221a and 221b in FIG. 14 represent the directions of the first electromotive forces V1 generated by the thermoelectric conversion elements 221. The arrows V11 are determined by the direction of the temperature gradient of the thermoelectric conversion elements 221 and the polarities of the thermoelectric conversion elements 221. Therefore, in FIG. 14, the arrows V11 correspond to the polarities of the thermoelectric conversion elements 221. The thermoelectric conversion elements 221b are provided in place of the first conductors 222 in the above embodiment and are connected in series with the thermoelectric conversion elements 221a through second conductors 223. In the first thermoelectric conversion device 22a and second thermoelectric conversion device 22b, the thermoelectric conversion elements 221a and thermoelectric conversion elements 221b are connected in series such that the first electromotive force V1 of the first thermoelectric conversion device 22a has a sign opposite to that of the second thermoelectric conversion device 22b. Thus, the first electromotive forces V1 generated by the first thermoelectric conversion device 22a and second thermoelectric conversion device 22b reinforce each other. This increases the thermoelectromotive force V generated by the entire thermoelectric conversion devices 22 on the basis of the temperature gradient.

While, in the above embodiment, the thermoelectromotive force measuring unit 3 and the user terminal 4 are separately provided, they may be integrated. The thermoelectromotive force measuring unit 3 may include the functional units 431 to 434 of the user terminal 4. That is, the above information processing may be performed by the thermoelectromotive force measuring unit 3.

While, in the above measuring system 1, the calculation unit 433 performs calculations using digital signals, this is not limiting. The calculation unit 433 may perform calculations using an analog circuit such as an addition circuit, or a combination of these.

In the present embodiment, the thermoelectromotive force measuring unit 3 may be disposed on the substrate 21, on which the thermoelectric conversion system 2 is disposed. In other words, the thermoelectric conversion system 2 and the thermoelectromotive force measuring unit 3 may be disposed on-board on the single substrate 21.

The thermoelectric conversion system 2 and the thermoelectromotive force measuring unit 3 may be configured to wirelessly communicate with each other. Thus, the thermoelectromotive force measuring unit 3 can measure the thermoelectromotive forces V by wirelessly communicating with the thermoelectric conversion system 2. In this case, the thermoelectric conversion system 2 does not have to include the port 23.

The external devices such as the thermoelectromotive force measuring unit 3 and user terminal 4, which perform the above information processing, may be on-premise or on cloud.

For example, on-cloud external devices may provide the above functions or processing in the form of Saas (Software as a Service) or cloud computing.

While, in the above embodiment, the thermoelectromotive force measuring unit 3 and user terminal 4 perform various types of storage and control, multiple external devices may be used in place of the thermoelectromotive force measuring unit 3 and user terminal 4. In other words, various types of information and programs may be distributed and stored in multiple external devices using a blockchain technology or the like.

The above embodiment is not limited to the measuring system 1 and may be an information processing method or an information processing program. The information processing method includes the steps performed by the measuring system 1. The information processing program causes at least one computer to perform the steps performed by the measuring system 1.

The measuring system 1 and the like may be provided in aspects below.
(1) A measuring system comprising: at least one substrate configured to exchange heat with an object to be measured, the substrate including at least one placement surface; and at least one first thermoelectric conversion device and at least one second thermoelectric conversion device, each of the thermoelectric conversion devices being disposed on the substrate such that a temperature gradient is generated due to exchange of heat with the object to be measured through the placement surface, and configured to generate a thermoelectromotive force on the basis of the temperature gradient wherein: the thermoelectromotive force includes a first electromotive force generated by a first thermoelectric conversion effect based on a component perpendicular to the placement surface of the temperature gradient and a second electromotive force generated by a second thermoelectric conversion effect based on an in-plane component parallel to the placement surface of the temperature gradient, and the at least one second thermoelectric conversion device is configured such that, for a temperature gradient in a substantially same direction as that of the at least one first thermoelectric conversion device, a sign of only one of the first electromotive force and the second electromotive force is opposite to a sign of the corresponding electromotive force of the at least one first thermoelectric conversion device.

Such a configuration allows for acquisition of information on the temperature gradient generated by the heat transferred through the substrate, from the thermoelectromotive forces induced by the thermoelectric conversion devices. The thermoelectromotive forces in the in-plane direction induced by the at least one first thermoelectric conversion device and the at least one second thermoelectric conversion device 22 each include both the first electromotive force based on the perpendicular component of the temperature gradient and second electromotive force based on the parallel component of the temperature gradient. Here, the direction of one of the first electromotive force and second electromotive force of both the thermoelectric conversion devices is opposite to the direction of the certain temperature gradient. This facilitates separation of the contribution of the perpendicular component of the temperature gradient and the contribution of the parallel component of the temperature gradient to the thermoelectromotive force.
(2) The measuring system according to (1), further comprising a conductor, wherein: the thermoelectric conversion devices each include a plurality of thermoelectric conversion elements each configured to generate the first thermoelectric conversion effect, the thermoelectric conversion elements are formed to extend in a direction in which the first electromotive force is generated, and the conductor is configured to connect the at least one first thermoelectric conversion device in series so as to amplify the first electromotive forces of the thermoelectric conversion elements of the at least one first thermoelectric conversion device.

Such a configuration increases the thermoelectromotive forces outputted from the thermoelectric conversion devices. This makes it easier to separate the contribution of the perpendicular component of the temperature gradient and the contribution of the parallel component of the temperature gradient in each thermoelectromotive force.
(3) The thermoelectric conversion device according to (2), wherein a direction in which the thermoelectric conversion elements of the at least one first thermoelectric conversion device extend is approximately parallel to a direction in which the thermoelectric conversion elements of the at least one second thermoelectric conversion device extend.

Such a configuration makes the difference between the thermoelectromotive force generated by the at least one first thermoelectric conversion device and the thermoelectromotive force generated by the at least one second thermoelectric conversion device more apparent. This allows for more accurate measurement of heat.
(4) The measuring system according to (2) or (3), wherein the thermoelectric conversion devices each include a meander structure in which the thermoelectric conversion elements and the conductor are disposed alternately.

Such a configuration allows for more compact mounting of the thermoelectric conversion devices.
(5) The thermoelectric conversion device according to any one of (2) to (4), wherein the thermoelectric conversion elements of the at least one first thermoelectric conversion device and the thermoelectric conversion elements of the at least one second thermoelectric conversion device include approximately identical compositions capable of generating the first thermoelectric conversion effect.

Such a configuration reduces the difference in electrical characteristics between the at least one first thermoelectric conversion device and the at least one second thermoelectric conversion device. This makes it easier to separate the contribution of the perpendicular component of the temperature gradient and the contribution of the parallel component of the temperature gradient to each thermoelectromotive force.
(6) The measuring system according to any one of (2) to (5), wherein: the thermoelectric conversion elements each includes a magnetic material having a magnetic structure capable of generating the first thermoelectric conversion effect, the magnetic structure having at least one of a first magnetic structure and a second magnetic structure formed to be time-reversal symmetric with respect to the first magnetic structure, the magnetic material of the thermoelectric conversion elements of the at least one first thermoelectric conversion device is configured such that a ratio of a magnetic domain corresponding to the second magnetic structure to a magnetic domain corresponding to the first magnetic structure is greater than one, and the magnetic material of the thermoelectric conversion elements of the at least one second thermoelectric conversion device is configured such that the ratio of the magnetic domain corresponding to the second magnetic structure to the magnetic domain corresponding to the first magnetic structure is smaller than one.
(7) The measuring system according to any one of (2) to (6), wherein: the thermoelectric conversion elements each contain a magnetic material having a magnetic structure capable of generating the first thermoelectric conversion effect, the magnetic structure causes spontaneous magnetization along an easy axis of magnetization, and the easy axis of magnetization extends in a direction approximately parallel to the placement surface and different from the direction in which the thermoelectric conversion elements extend.

Such a configuration makes it possible to adjust the characteristics of the thermoelectric conversion devices by adjusting the ratio of the magnetic domains using the external magnetic field.
(8) The measuring system according to (7), wherein the magnetic structure is an antiferromagnetic structure, a canted antiferromagnetic structure, or a ferrimagnetic structure.

Such a configuration makes the spontaneous magnetization caused by the magnetic material smaller in magnitude than that when the magnetic structure is a ferromagnetic structure. This reduces noise caused by the spontaneous magnetization.
(9) The measuring system according to (7), wherein the magnetic structure is a ferromagnetic structure.

Such a configuration facilitates domain control using the external magnetic field, and the like.

(10) The measuring system according to any one of (2) to (9), wherein the thermoelectric conversion elements are formed as thin films having a thickness in a direction perpendicular to the placement surface.

Such a configuration downsizes the thermoelectric conversion devices compared to those having a three-dimensional structure in which thermoelectric conversion elements 221 are stacked in the thickness direction.

(11) The measuring system according to any one of (1) to (10), wherein the at least one first thermoelectric conversion device and the at least one second thermoelectric conversion device are disposed on a single substrate of the at least one substrate.

Such a configuration suppresses errors in the positional relationship between the at least one first thermoelectric conversion device and the at least one second thermoelectric conversion device compared to those when the at least one first thermoelectric conversion device and the at least one second thermoelectric conversion device are separately mounted on the object to be measured.
(12) The measuring system according to any one of (1) to (11), wherein: the at least one first thermoelectric conversion device and the at least one second thermoelectric conversion device are disposed on a single placement surface of the at least one placement surface, and at least one of the thermoelectric conversion devices closest to the at least one first thermoelectric conversion device on the single placement surface is the at least one second thermoelectric conversion device.

Such a configuration reduces the difference between heat flowing into the at least one first thermoelectric conversion device and heat flowing into the at least one second thermoelectric conversion device. This allows for more accurate thermal measurement.
(13) The measuring system according to any one of (1) to (12), wherein the thermoelectric conversion devices each include at least a pair of measuring terminals capable of measuring the thermoelectromotive force.

Such a configuration reduces noise when measuring the thermoelectromotive forces generated by series-connected different thermoelectric conversion devices.
(14) The measuring system according to any one of (1) to (13), further comprising at least one thermoelectromotive force measuring unit configured to measure the thermoelectromotive force of the at least one first thermoelectric conversion device and the thermoelectromotive force of the at least one second thermoelectric conversion device.
(15) The measuring system according to (14), further comprising at least one processor configured to execute a program so as to execute each of steps including: an acquisition step of acquiring the thermoelectromotive force of the at least one first thermoelectric conversion device and the thermoelectromotive force of the at least one second thermoelectric conversion device measured by the thermoelectromotive force measuring unit; and an output step of outputting a first voltage value calculated such that the second electromotive force of the at least one first thermoelectric conversion device and the second electromotive force of the at least one second thermoelectric conversion device included in the acquired thermoelectromotive forces cancel out each other.

Such a configuration reduces the contribution of the second electromotive force included in each thermoelectromotive force and thus allows for more accurate estimation of the first electromotive force.
(16) The measuring system according to (15), wherein the output step includes outputting a second voltage value calculated such that the first electromotive force of the at least one first thermoelectric conversion device and the second electromotive force of the at least one first thermoelectric conversion device included in the thermoelectromotive forces cancel out each other.

Such a configuration allows for more accurate estimation of the contribution of the Seebeck effect from the second voltage value calculated from the acquired thermoelectromotive forces. This allows for precise detection of the heat flow along the placement surface.
(17) The measuring system according to (16), wherein: the steps further include a specification step of receiving specification of at least one of the first voltage value and the second voltage value, and the output step includes outputting the voltage value corresponding to the received specification.

Such a configuration allows for estimation of the contribution of the electromotive force desired by a user of the first and second electromotive forces. This increases the convenience of the measurement system.
(18) The measuring system according to any one of (1) to (17), wherein the thermoelectric conversion devices are electrically insulated from each other.

Such a configuration reduces noise such as contact resistance caused by the electrical connection of the thermoelectric conversion devices.
(19) A method for producing a measuring system, the measuring system including at least one substrate configured to exchange heat with an object to be measured, the substrate including at least one placement surface; and at least one first thermoelectric conversion device and at least one second thermoelectric conversion device, each of the thermoelectric conversion devices being disposed on the substrate such that a temperature gradient is generated due to exchange of heat with the object to be measured through the placement surface, and configured to generate a thermoelectromotive force on the basis of the temperature gradient wherein: the thermoelectromotive force includes a first electromotive force generated by a first thermoelectric conversion effect based on a component perpendicular to the placement surface of the temperature gradient and a second electromotive force generated by a second thermoelectric conversion effect based on an in-plane component parallel to the placement surface of the temperature gradient, and the at least one second thermoelectric conversion device is configured such that, for a temperature gradient in a substantially same direction as that of the at least one first thermoelectric conversion device, a sign of only one of the first electromotive force and the second electromotive force is opposite to a sign of the corresponding electromotive force of the at least one first thermoelectric conversion device, the thermoelectric conversion devices each comprise at least one thermoelectric conversion element configured to generate the first thermoelectric conversion effect, and the at least one thermoelectric conversion element contains a magnetic material having a magnetic structure capable of generating the first thermoelectric conversion effect, the method comprising: a disposition step of disposing precursors of the thermoelectric conversion devices each comprising the at least one thermoelectric conversion element on the placement surface; and an energy supply step of executing a local energy supply to the at least one thermoelectric conversion element of each of the disposed precursors to align a magnetic domain included in the at least one thermoelectric conversion element, the local energy supply including applying an external magnetic field at least in a direction approximately perpendicular to both a direction in which the first electromotive force is generated and a direction perpendicular to the placement surface, wherein a direction of the external magnetic field applied to the precursor of the at least one first thermoelectric conversion device is opposite to a direction of the external magnetic field applied to the precursor of the at least one second thermoelectric conversion device.
(20) The method according to (19), wherein the local energy supply further includes locally heating the at least one thermoelectric conversion element. Of course, these aspects are not limiting.

Finally, while the various embodiments according to the present disclosure have been described above, the embodiments are only illustrative and are not intended to limit the scope of the invention. The novel embodiments can be carried out in other various forms, and various omissions, replacements, or changes can be made thereto without departing from the gist of the invention. The embodiments and modifications thereof are included in the scope and gist of the present invention, as well as included in the scope of the invention set forth in the claims and equivalents thereof.

1. A measuring system comprising:
at least one substrate configured to exchange heat with an object to be measured, the substrate including at least one placement surface; and
at least one first thermoelectric conversion device and at least one second thermoelectric conversion device, each of the thermoelectric conversion devices being disposed on the substrate such that a temperature gradient is generated due to exchange of heat with the object to be measured through the placement surface, and configured to generate a thermoelectromotive force on the basis of the temperature gradient wherein:
the thermoelectromotive force includes a first electromotive force generated by a first thermoelectric conversion effect based on a component perpendicular to the placement surface of the temperature gradient and a second electromotive force generated by a second thermoelectric conversion effect based on an in-plane component parallel to the placement surface of the temperature gradient, and
the at least one second thermoelectric conversion device is configured such that, for a temperature gradient in a substantially same direction as that of the at least one first thermoelectric conversion device, a sign of only one of the first electromotive force and the second electromotive force is opposite to a sign of the corresponding electromotive force of the at least one first thermoelectric conversion device.

2. The measuring system according to claim 1, further comprising a conductor, wherein:
the thermoelectric conversion devices each include a plurality of thermoelectric conversion elements each configured to generate the first thermoelectric conversion effect,
the thermoelectric conversion elements are formed to extend in a direction in which the first electromotive force is generated, and
the conductor is configured to connect the at least one first thermoelectric conversion device in series so as to amplify the first electromotive forces of the thermoelectric conversion elements of the at least one first thermoelectric conversion device.

3. The measuring system according to claim 2, wherein
a direction in which the thermoelectric conversion elements of the at least one first thermoelectric conversion device extend is approximately parallel to a direction in which the thermoelectric conversion elements of the at least one second thermoelectric conversion device extend.

4. The measuring system according to claim 2, wherein
the thermoelectric conversion devices each include a meander structure in which the thermoelectric conversion elements and the conductor are disposed alternately.

5. The measuring system according to claim 2, wherein
the thermoelectric conversion elements of the at least one first thermoelectric conversion device and the thermoelectric conversion elements of the at least one second thermoelectric conversion device include approximately identical compositions capable of generating the first thermoelectric conversion effect.

6. The measuring system according to claim 2, wherein:
the thermoelectric conversion elements each includes a magnetic material having a magnetic structure capable of generating the first thermoelectric conversion effect, the magnetic structure having at least one of a first magnetic structure and a second magnetic structure formed to be time-reversal symmetric with respect to the first magnetic structure,
the magnetic material of the thermoelectric conversion elements of the at least one first thermoelectric conversion device is configured such that a ratio of a magnetic domain corresponding to the second magnetic structure to a magnetic domain corresponding to the first magnetic structure is greater than one, and
the magnetic material of the thermoelectric conversion elements of the at least one second thermoelectric conversion device is configured such that the ratio of the magnetic domain corresponding to the second magnetic structure to the magnetic domain corresponding to the first magnetic structure is smaller than one.

7. The measuring system according claim 2, wherein:
the thermoelectric conversion elements each contain a magnetic material having a magnetic structure capable of generating the first thermoelectric conversion effect,
the magnetic structure causes spontaneous magnetization along an easy axis of magnetization, and
the easy axis of magnetization extends in a direction approximately parallel to the placement surface and different from the direction in which the thermoelectric conversion elements extend.

8. The measuring system according to claim 7, wherein
the magnetic structure is an antiferromagnetic structure, a canted antiferromagnetic structure, or a ferrimagnetic structure.

9. The measuring system according to claim 7, wherein
the magnetic structure is a ferromagnetic structure.

10. The measuring system according to claim 2, wherein
the thermoelectric conversion elements are formed as thin films having a thickness in a direction perpendicular to the placement surface.

11. The measuring system according to claim 1, wherein
the at least one first thermoelectric conversion device and the at least one second thermoelectric conversion device are disposed on a single substrate of the at least one substrate.

12. The measuring system according to claim 1, wherein:
the at least one first thermoelectric conversion device and the at least one second thermoelectric conversion device are disposed on a single placement surface of the at least one placement surface, and
at least one of the thermoelectric conversion devices closest to the at least one first thermoelectric conversion device on the single placement surface is the at least one second thermoelectric conversion device.

13. The measuring system according to claim 1, wherein
the thermoelectric conversion devices each include at least a pair of measuring terminals capable of measuring the thermoelectromotive force.

14. The measuring system according to claim 1, further comprising
at least one thermoelectromotive force measuring unit implemented by at least one measuring instrument configured to measure the thermoelectromotive force of the at least one first thermoelectric conversion device and the thermoelectromotive force of the at least one second thermoelectric conversion device.

15. The measuring system according to claim 14, further comprising at least one processor configured to execute a program so as to execute each of steps including:
an acquisition step of acquiring the thermoelectromotive force of the at least one first thermoelectric conversion device and the thermoelectromotive force of the at least one second thermoelectric conversion device measured by the thermoelectromotive force measuring unit; and
an output step of outputting a first voltage value calculated such that the second electromotive force of the at least one first thermoelectric conversion device and the second electromotive force of the at least one second thermoelectric conversion device included in the acquired thermoelectromotive forces cancel out each other.

16. The measuring system according to claim 15, wherein
the output step includes outputting a second voltage value calculated such that the first electromotive force of the at least one first thermoelectric conversion device and the second electromotive force of the at least one first thermoelectric conversion device included in the thermoelectromotive forces cancel out each other.

17. The measuring system according to claim 16, wherein:
the steps further include a specification step of receiving specification of at least one of the first voltage value and the second voltage value, and
the output step includes outputting the voltage value corresponding to the received specification.

18. The measuring system according to claim 1, wherein
the thermoelectric conversion devices are electrically insulated from each other.

19. A method for producing a measuring system,
the measuring system including at least one substrate configured to exchange heat with an object to be measured, the substrate including at least one placement surface; and
at least one first thermoelectric conversion device and at least one second thermoelectric conversion device, each of the thermoelectric conversion devices being disposed on the substrate such that a temperature gradient is generated due to exchange of heat with the object to be measured through the placement surface, and configured to generate a thermoelectromotive force on the basis of the temperature gradient wherein:
the thermoelectromotive force includes a first electromotive force generated by a first thermoelectric conversion effect based on a component perpendicular to the placement surface of the temperature gradient and a second electromotive force generated by a second thermoelectric conversion effect based on an in-plane component parallel to the placement surface of the temperature gradient, and
the at least one second thermoelectric conversion device is configured such that, for a temperature gradient in a substantially same direction as that of the at least one first thermoelectric conversion device, a sign of only one of the first electromotive force and the second electromotive force is opposite to a sign of the corresponding electromotive force of the at least one first thermoelectric conversion device,
the thermoelectric conversion devices each comprise at least one thermoelectric conversion element configured to generate the first thermoelectric conversion effect, and
the at least one thermoelectric conversion element contains a magnetic material having a magnetic structure capable of generating the first thermoelectric conversion effect,
the method comprising:
a disposition step of disposing precursors of the thermoelectric conversion devices each comprising the at least one thermoelectric conversion element on the placement surface; and
an energy supply step of executing a local energy supply to the at least one thermoelectric conversion element of each of the disposed precursors to align a magnetic domain included in the at least one thermoelectric conversion element, the local energy supply including applying an external magnetic field at least in a direction approximately perpendicular to both a direction in which the first electromotive force is generated and a direction perpendicular to the placement surface, wherein
a direction of the external magnetic field applied to the precursor of the at least one first thermoelectric conversion device is opposite to a direction of the external First Preliminary Amendment magnetic field applied to the precursor of the at least one second thermoelectric conversion device.

20. The method according to claim 19, wherein
the local energy supply further includes locally heating the at least one thermoelectric conversion element.
